(19) United States
(12) Patent Application Publication
(10) Pub. No.: US 2017/0228060 A1
(43) Pub. Date: Aug. 10, 2017

(54) Appliance User Interface Panel Having Integrated Components

(71) Applicant: General Electric Company, Schenectady, NY (US)

(72) Inventor: Phillip John Duckworth, Louisville, KY (US)

(21) Appl. No.: 15/017,703

(22) Filed: Feb. 8, 2016

(51) Int. Cl. G06F 3/044; D06F 39/00; H05K 1/11; H05K 5/00; H05K 1/18; H05K 3/00

(52) U.S. Cl. CPC G06F 3/044; H05K 1/181; H05K 3/0026; H05K 1/115; H05K 5/0017; H05K 1/182; D06F 39/005; H05K 2201/10431

(57) ABSTRACT

A user interface for an appliance is provided, including a user interface panel and a control component attached to the user interface panel. The user interface panel includes a plurality of traces for providing an electrical connection for the control component. The plurality of traces are integrally formed with the user interface panel such that the plurality of traces and the user interface panel are a single, unitary component. In some embodiments, the unitary user interface panel is curved. A method for forming a unitary user interface of an appliance also is provided, including establishing courses of a plurality of traces of the unitary user interface; converting the courses into control data for use in a laser direct structuring process; and using the laser direct structuring process to integrally form the plurality of traces with a user interface panel to form a unitary user interface panel.

### FIELD OF THE INVENTION

The present subject matter relates generally to an appliance and a user interface panel for an appliance. More particularly, the present subject matter relates to appliances having user interfaces with integrated components.

### BACKGROUND OF THE INVENTION

Washing machine appliances generally include a tub for containing wash fluid, e.g., water, detergent, fabric softener, bleach, and/or combinations thereof, during operation of such washing machine appliances. A wash basket is rotatably mounted within the tub and defines a wash chamber for receipt of articles for washing. During operation of such washing machine appliances, wash fluid is directed into the tub and onto a load of articles within the wash basket. The wash basket and/or an agitation element can rotate at various speeds to agitate articles within the wash basket in the wash fluid, to wring wash fluid from articles within the wash basket, etc.

Typically, a user interface or control panel is provided having one or more controls that a user of the appliance may manipulate to select various options for the operation of the washing machine appliance. For example, the user may select the size of the load of articles and the type of articles in the wash chamber, as well as other features of the articles or the washing machine that may impact a wash, rinse, or other cycle. The appliance usually is operated by a controller or other control mechanism based at least in part on such user selections. Other appliances, such as, e.g., dryer appliances, cooktop appliances, and oven range appliances, also may include a user interface panel including controls that a user may manipulate to select options for operating the appliance.

Some user interface panel assemblies include touch-type controls, whereby the user touches a lens or cover panel of the user interface panel assembly to select an option. In addition to or instead of touch-type controls, user interface panel assemblies may include rotatable knobs, buttons, and the like for selecting various options. Usually, the user manipulates the controls on or at a decorative panel of the appliance, and the controls are in operative communication with a separate printed circuit board (PCB) panel that controls the operations of the appliance or that communicates with the controller or other control mechanism to control the appliance. Other user interface components, such as, e.g., lights and micro-switches, typically also are mounted separately from the panel with which the user interacts. Such separation between the user interface panel and the user interface components can limit the user interface design, as well as the effectiveness of the user interface. For example, because PCBs typically are flat, rounded or curved user interface panels are difficult to produce, requiring the PCB to be broken into multiple elements to mount the flat PCB component to the curved user interface panel. As another example, capacitive touch-type controls require an additional capacitive sensing layer between the user interface panel and the PCB to conduct the touch inputs to the PCB.

Accordingly, a user interface for an appliance having a user interface panel with integrated user interface components would be useful. More particularly, a user interface for an appliance including a user interface panel having integrated circuit traces would be beneficial. A user interface for an appliance including an integral user interface panel and circuit traces as well as features for attaching a control component to the user interface panel also would be advantageous.

### BRIEF DESCRIPTION OF THE INVENTION

Aspects and advantages of the invention will be set forth in part in the following description, or may be obvious from the description, or may be learned through practice of the invention.

In one exemplary embodiment of the present disclosure, a user interface for an appliance is provided. The user interface includes a user interface panel and a control component attached to the user interface panel. The user interface panel includes a plurality of traces for providing an electrical connection for the control component. The plurality of traces are integrally formed with the user interface panel such that the plurality of traces and the user interface panel are a single, unitary component.

In another exemplary embodiment of the present disclosure, a user interface for an appliance is provided. The user interface includes a user interface panel and a control component attached to the user interface panel. The user interface panel includes a plurality of traces for providing an electrical connection for the control component. The plurality of traces are integrally formed with the user interface panel such that the plurality of traces and the user interface panel are a single, unitary component, and the unitary user interface panel is curved.

In a further exemplary embodiment of the present disclosure, a method for forming a unitary user interface of an appliance is provided. The method includes establishing courses of a plurality of traces of the unitary user interface; converting the courses into control data for use in a laser direct structuring process; and integrally forming the plurality of traces with a user interface panel using the laser direct structuring process. The integral user interface panel and traces form a unitary user interface panel.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 provides a side, perspective view of a washing machine appliance according to an exemplary embodiment of the present subject matter, with a door of the washing machine appliance shown in a closed position.

FIG. 2 provides a side, perspective view of the washing machine appliance of FIG. 1, with the door of the washing machine appliance shown in an open position.

FIG. 3 provides a schematic view of a unitary user interface panel of the appliance of FIG. 1 according to an exemplary embodiment of the present subject matter.

FIGS. 4A, 4B, and 4C provide schematic views of a portion of the unitary user interface panel of FIG. 3 according to an exemplary embodiment of the present subject matter.

FIGS. 5A, 5B, 5C, and 5D provide schematic views of another portion of the unitary user interface panel of FIG. 3 according to an exemplary embodiment of the present subject matter.

FIG. 6A provides a schematic view of a unitary user interface panel of the appliance of FIG. 1 according to an exemplary embodiment of the present subject matter.

FIG. 6B provides a cross-section view of the unitary user interface panel of FIG. 6A according to an exemplary embodiment of the present subject matter.

FIG. 7 provides a chart illustrating a method for forming a unitary user interface panel according to an exemplary embodiment of the present subject matter.

FIG. 8 provides a chart illustrating a method for forming a unitary user interface panel according to another exemplary embodiment of the present subject matter.

### DETAILED DESCRIPTION OF THE INVENTION

Reference will now be made in detail to present embodiments of the invention, one or more examples of which are illustrated in the accompanying drawings. The detailed description uses numerical and letter designations to refer to features in the drawings. Like or similar designations in the drawings and description have been used to refer to like or similar parts of the invention. Further, each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

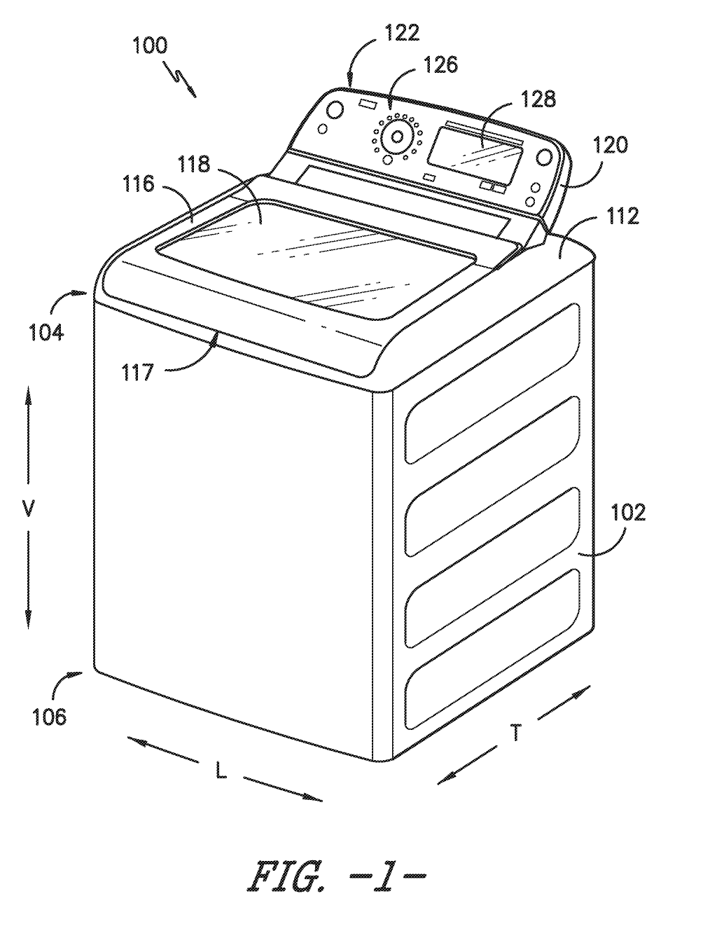

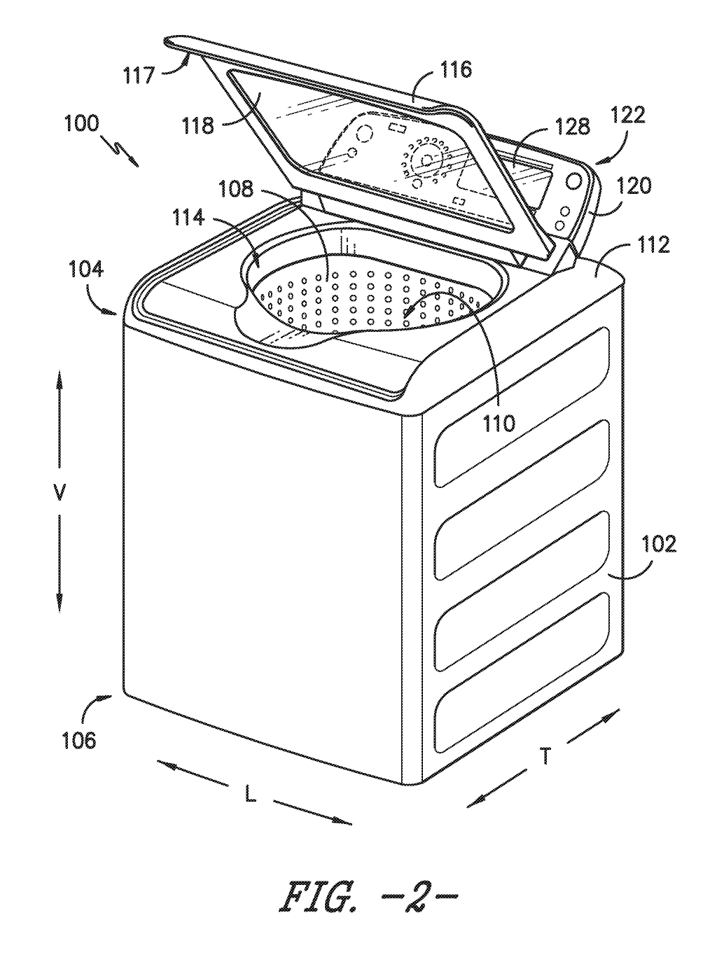

Referring now to the drawings, wherein identical numerals indicate the same elements throughout the figures, FIGS. 1 and 2 provide side, perspective views of a washing machine appliance according to an exemplary embodiment of the present subject matter. More particularly, FIG. 1 illustrates an exemplary embodiment of a vertical axis washing machine or washer appliance 100 with a lid or door 116 in a closed position. FIG. 2 illustrates washing machine appliance 100 with door 116 in an open position. While described in the context of an embodiment of a vertical axis washing machine appliance 100, using the teachings disclosed herein it will be understood that vertical axis washing machine appliance 100 is provided by way of example only. Other washing machine appliances having different configurations, different appearances, and/or different features may be utilized with the present subject matter as well, e.g., horizontal axis washing machines. Additionally, the present subject matter also may be used with other appliances, such as cooktop appliances, oven range appliance, and dryer appliances, to name but a few examples.

Washing machine appliance 100 has a cabinet 102 that extends between a top 104 and a bottom 106 along a vertical direction V. A wash basket 108 (FIG. 2) is rotatably mounted within cabinet 102. Wash basket 108 is received within a wash tub or wash chamber 110 (FIG. 2) and is configured for receipt of articles (not shown) for washing, such as clothes and the like. Wash tub 110 holds wash and rinse fluids for agitation with the articles in wash basket 108. In addition, some embodiments of washing machine appliance 100 may include a fluid additive dispenser (not shown) for receipt of one or more fluid additives, e.g., detergent, fabric softener, and/or bleach, to dispense to the articles during one or more cycles of washing machine appliance 100. Such cycles of washing machine 100 may include, e.g., a wash cycle, a rinse cycle, and a spin cycle.

Cabinet 102 of washing machine appliance 100 has a top panel 112. Top panel 112 defines an opening 114 (FIG. 2) that permits user access to wash basket 108 of wash tub 110. Door 116, rotatably mounted to top panel 112, permits selective access to opening 114; in particular, door 116 selectively rotates between a closed position shown in FIG. 1 and an open position shown in FIG. 2. In the closed position, door 116 inhibits access to wash basket 108. Conversely, in the open position, a user can access wash basket 108. A window 118 in door 116 permits viewing of wash basket 108 when door 116 is in the closed position, e.g., during operation of washing machine appliance 100. Door 116 also includes a handle 117 that, e.g., a user may pull and/or lift when opening and closing door 116.

As previously stated, it should be appreciated that the present subject matter is not limited to any particular style, model, or configuration of washing machine appliance. Thus, the exemplary embodiment of washer 100 depicted in FIGS. 1 and 2 is provided for illustrative purposes only. For example, although door 116 is illustrated as mounted to top panel 112, alternatively, door 116 may be mounted to cabinet 102 or any outer suitable support. As other examples, window 118 in door 116 may be omitted, or washing machine 100 may be a horizontal axis washing machine. Other differences may be applied as well.

Referring particularly to FIG. 1, a backsplash 120 extends from top panel 112. Backsplash 120 supports a user interface 122 for the appliance, i.e., backsplash 120 is a user interface support. User interface 122 comprises a user interface panel 124. In some embodiments, user interface panel 124 may be mounted or otherwise attached to or on backsplash 120. As further depicted in FIG. 1, user interface panel 124 has at least one input selector 126. As shown in FIG. 1, washing machine appliance 100 includes a variety of input selectors 126, including knobs, buttons, and touch-type selectors, such as a capacitive touch sensing system. A user may manipulate one or more input selectors 126 to select one or more cycles or features of appliance 100. A display 128 of user interface 122 indicates selected features, an operation mode, a countdown timer, and/or other items of interest to appliance users regarding operation of appliance 100.

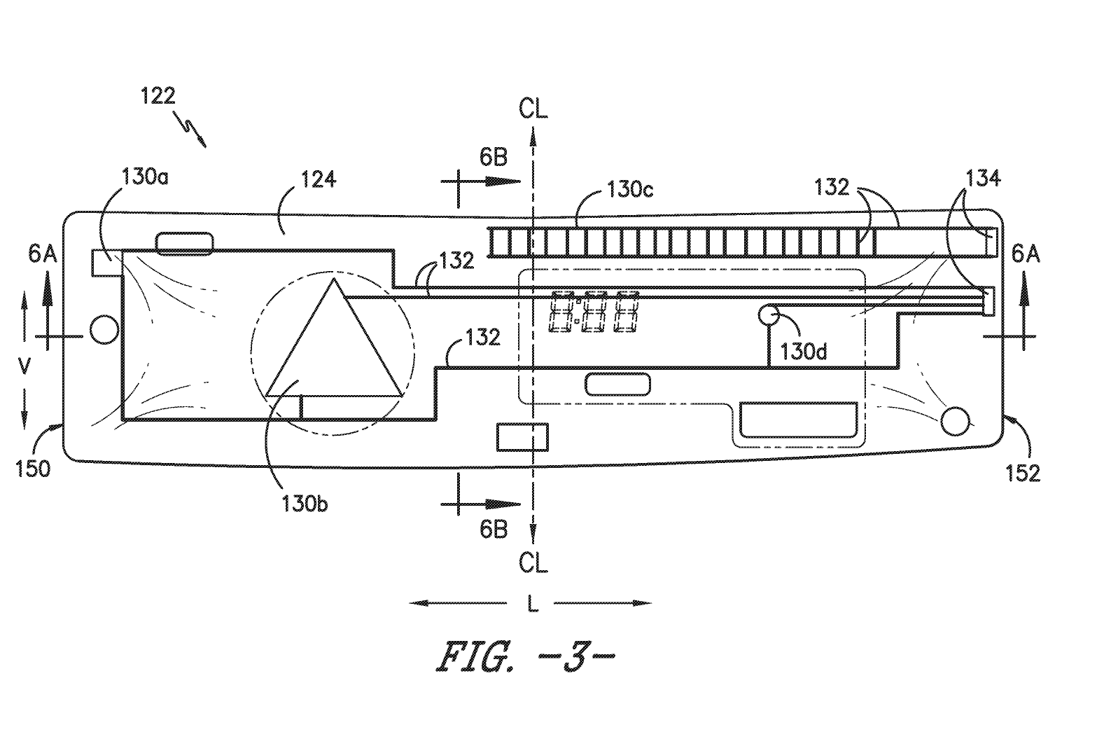

FIG. 3 provides a schematic view of user interface panel 124 of washing machine appliance 100 according to an exemplary embodiment of the present subject matter. As depicted in FIG. 3, a variety of control components 130 are mounted or attached to user interface panel 124. A plurality of traces 132 electrically connect control components 130 and connectors 134, which in turn connect control components 130 to a power source (not shown) and/or other control panels or components. That is, traces 132 provide an electrical connection for the one or more control components 130 attached to user interface panel 124. For example, in one embodiment, traces 132 may electrically connect control components 130 with a separate printed circuit board (PCB) via connectors 134. In another embodiment, traces 132 may connect control components with a controller for operating the various components of washing machine appliance 100 to execute machine cycles and features, e.g., selected by the user using input selectors 126. As described in greater detail below, traces 132 are integrally formed with user interface panel 124 such that traces 132 and user interface panel 124 are a single, unitary component.

In the embodiment of user interface panel 124 depicted in FIG. 3, control components 130 include a micro-switch 130a, an encoder 130b, a capacitive touch sensing matrix 130c, and a light 130d, which may be a light emitting diode (LED). Of course, in alternative embodiments, different or additional control components 130 also may be provided. As shown, traces 132 connect each control component 130a, 130b, 130c, and 130d to connectors 134.

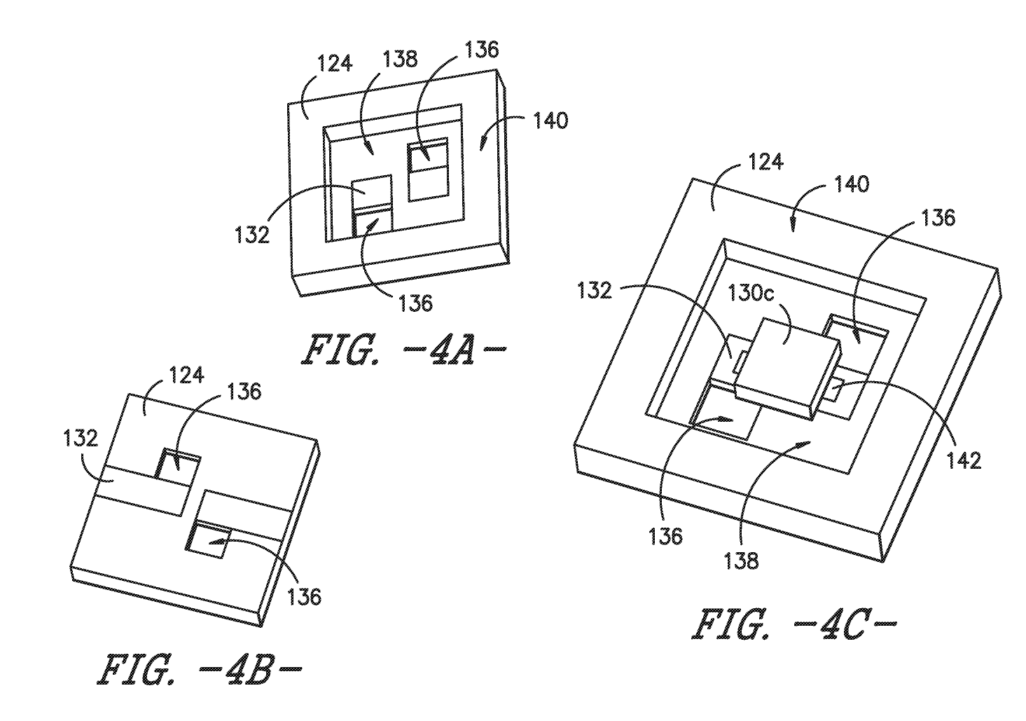

Control components 130a, 130b, 130c, and 130d are mounted directly to user interface panel 124. Referring now to FIGS. 4A, 4B, and 4C, which provide a schematic representation of a portion of user interface panel 124 according to an exemplary embodiment of the present subject matter, some components may be surface mounted to user interface panel 124 and, as such, may be surface mount control components 130e. As shown in FIG. 4A, user interface panel 124 may define one or more apertures 136 in an area 138 where the surface mount control component 130e will be mounted. The surface mount area 138 may be a depression in a surface 140 of user interface panel 124, such that the surface mount control component 130e is at least partially recessed within user interface panel 124. A trace 132 wraps or otherwise extends into the one or more apertures 136 in area 138 such that surface mount control component 130e may be in contact with trace 132. As illustrated in FIG. 4C, solder 142 may be applied between surface mount control component 130e and user interface panel 124 to secure control component 130 to panel 124.

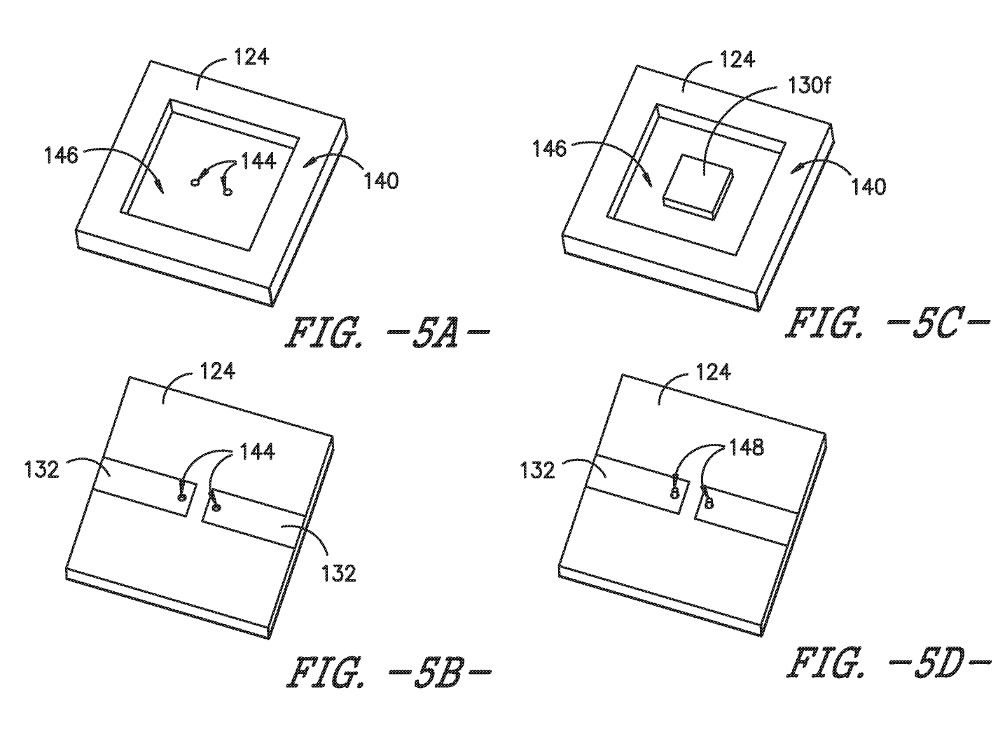

Referring now to FIGS. 5A, 5B, 5C, and 5D, which provide a schematic representation of a portion of user interface panel 124 according to an exemplary embodiment of the present subject matter, some components may be through hole components mounted to user interface panel 124 using through holes in panel 124. Such components may be referred to as through hole control components 130f. As shown in FIG. 5A, user interface panel 124 may define one or more through holes 144 in an area 146 where the through hole control component 130f will be mounted. The through hole mount area 146 may be a depression in surface 140 of user interface panel 124, such that the through hole control component 130 is at least partially recessed within user interface panel 124. A trace 132 surrounds at least a portion of each of the one or more through holes 144 such that through hole control component 130f may be in contact with trace 132. As illustrated in FIG. 5B, trace 132 surrounds each of the two illustrated through holes 144 in the plane in which trace 132 extends. Referring particularly to FIGS. 5C and 5D, through hole control component 130f may be mounted on user interface panel 124 such that a leg 148 of through hole control component 130f extends through each adjacent through hole 144. Further, although not shown in the depicted embodiment, solder may be applied, e.g., at legs 148 of through hole control component 130f to secure control component 130f to panel 124.

As previously stated, traces 132 are integrally formed with user interface panel 124 such that user interface panel 124 and the plurality of traces 132 are a single, unitary component. In exemplary embodiments, traces 132 are integrally formed with user interface panel 124 using a laser direct structuring (LDS) process. In other embodiments, traces 132 and user interface panel 124 are integrally formed using an additive manufacturing process, such as fused deposition modeling (FDM), selective laser sintering (SLS), stereolithography (SLA), digital light processing (DLP), direct metal laser sintering (DMLS), laser net shape manufacturing (LNSM), electron beam sintering, or another known additive process. In still other embodiments, traces 132 may be integrally formed with user interface panel 124 by other suitable processes.

The term “unitary” as used herein denotes that the associated component, such as user interface panel 124 described herein, is made as a single piece during manufacturing, i.e., from a continuous piece of material. Thus, a unitary component has a monolithic construction and is different from a component that has been made from a plurality of component pieces that have been joined together to form a single component. More specifically, in the exemplary embodiment of FIG. 3, user interface panel 124 and traces 132 are constructed as a single unit or piece to produce a unitary user interface panel.

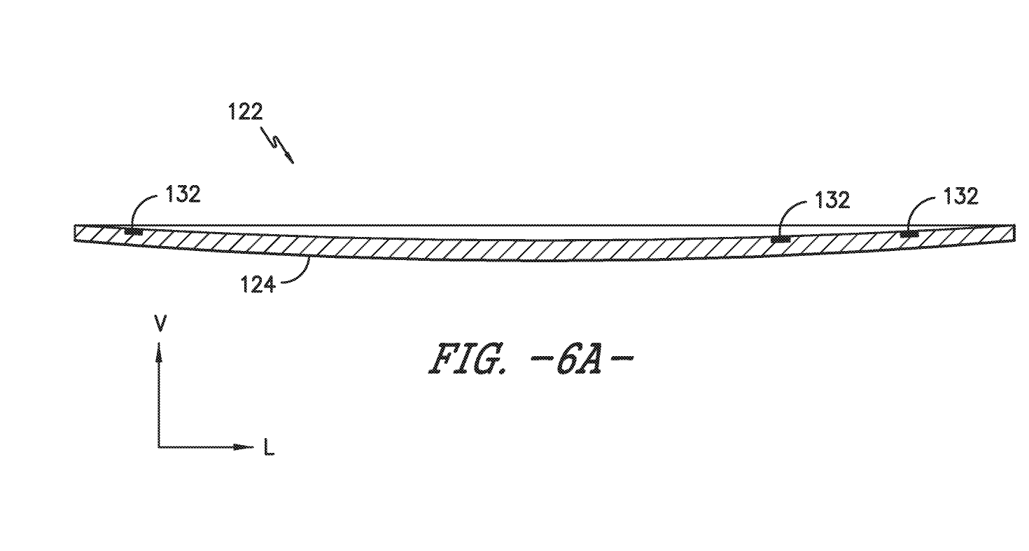

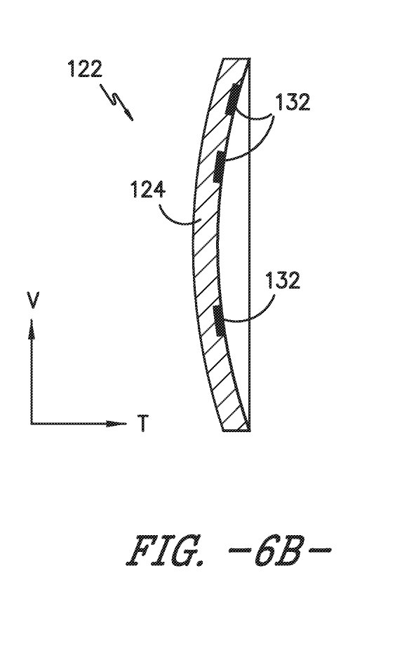

By integrally forming traces 132 with user interface panel 124 to form a unitary user interface panel, the geometry of the unitary user interface panel is not limited by the challenges of, e.g., mounting one or more printed circuit boards in proximity to electrically connect control components 130. That is, the functionality provided by a PCB is effectively integrated into the unitary user interface panel, and as such, user interface panel 124 may have a more complex geometry than a flat, generally planar surface. In an exemplary embodiment illustrated in FIGS. 6A and 6B, user interface panel 124, having integral traces 132, may be curved. FIG. 6B provides a cross-section of user interface panel 124 along a first plane that includes the vertical direction V and a transverse direction T. As such, panel 124 is curved along a first direction parallel to the vertical direction V. In other embodiments, user interface panel 124 may be curved along multiple directions, e.g., along the first direction parallel to the vertical direction V and a second direction parallel to the lateral direction L. For example, as shown in FIG. 6A, panel 124 may be curved from a vertical centerline CL toward a first side 150 of panel 124 and from centerline CL toward a second side 152 of panel 124, such that panel 124 is curved along the second direction parallel to the lateral direction L. Accordingly, curved unitary user interface panel 124 may be curved within the first plane shown in FIG. 6B and within any parallel plane drawn through curved panel 124 from first side 150 to second side 152 of panel 124.

Curved unitary user interface panel 124 may have a same or a different radius of curvature along each direction and in each plane. As an example, user interface panel 124 may have a smaller radius of curvature near a centerline CL and a larger radius of curvature near first and second sides 150, 152 such that panel 124 is more curved at or near its center and flatter at or near its sides. As another example, user interface panel 124 may have substantially the same radius of curvature along its length from first side 150 to second side 152. Of course, in some embodiments, unitary user interface panel 124 may be generally flat.

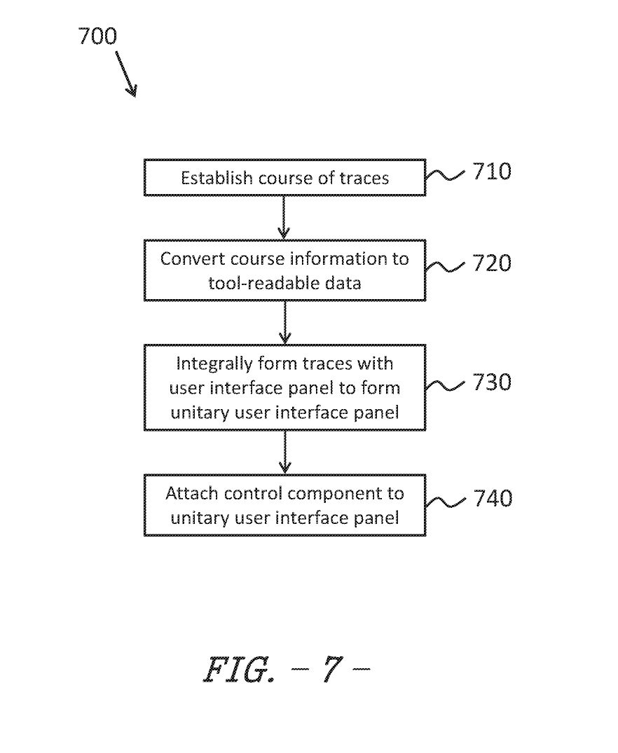

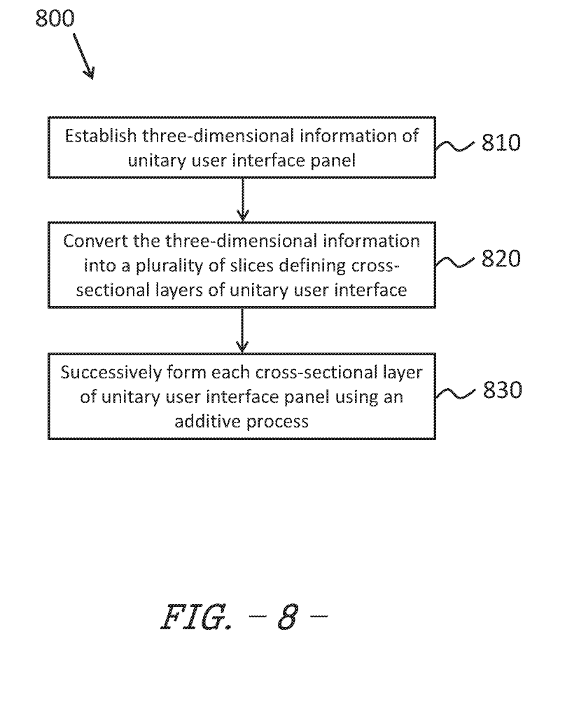

FIGS. 7 and 8 provide charts illustrating methods for forming a unitary user interface panel for an appliance according to exemplary embodiments of the present subject matter. Methods 700 and 800 permit formation of the various features of a unitary user interface panel, and as such, method 700 and/or method 800 may be used to produce the unitary user interface panel 124 as illustrated in FIGS. 3, 4A-4C, 5A-5D, 6A, and 6B, as well as variations of the illustrated embodiments. It will be appreciated that methods 700 and/or 800 also may be used to form a unitary user interface panel for any suitable appliance.

FIG. 7 illustrates method 700 for forming a unitary user interface panel using a laser direct structuring process. A laser direct structuring process fabricates components having circuit traces by first forming a component from an appropriate material. Next, the component is laser processed to form trace tracks; that is, a laser is used to form tracks of circuit traces on the component. Then, the trace tracks are metallized to produce traces integral with the component.

More particularly, as shown at step 710, a course or path of each trace 132 of the plurality of traces 132 is established. The course or path of a trace is its route from a control component 130 to a connector 134. The courses of the plurality of traces, together with the position of control components 130, establish the layout of the circuit integrated with user interface panel 124. Next, as shown at step 720, the courses of the plurality of traces are converted to tool-readable control data. For a laser direct structuring process, the course information is converted into a control language or code for controlling a laser, i.e., for guiding the laser along the component in the pattern of the courses.

Then, at step 730, the plurality of traces 132 are integrally formed with user interface panel 124 to produce a unitary user interface panel. In some embodiments, integrally forming traces 132 with user interface panel 124 may comprise first injection molding user interface panel 124 from a suitable material, such as, e.g., a duroplast or a thermoplastic material. Then, the molded user interface panel 124 is laser processed to provide trace tracks in the user interface panel. Next, user interface panel 124 having laser processed trace tracks is metallized, e.g., by placing the panel within an electroless copper bath, to raise traces 132 within the trace tracks.

As shown at step 740, after traces 132 are integrally formed with user interface panel 124 to produce the unitary user interface panel, one or more control components 130 may be attached to the unitary user interface panel. Control components 130 may be surface mount or through hole components 130e, 130f attached to unitary user interface panel 124 as described above with respect to FIGS. 4A-4C and 5A-5D. Thus, method 700 also may comprise defining one or more apertures 136 within the unitary user interface panel and extending a trace 132 through one or more apertures 136 such that a surface mount control component 130e may be attached to unitary user interface panel 124 in contact with trace 132. Alternatively or additionally, method 700 may include defining through holes 144 within the unitary user interface panel and attaching a through hole control component 130f to unitary user interface panel 124 such that legs 148 of the component 130 extend through through holes 144.

FIG. 8 illustrates method 800 for forming a unitary user interface panel using an additive manufacturing process. As previously stated, suitable additive manufacturing processes for fabricating the unitary user interface panel may include fused deposition modeling (FDM), selective laser sintering (SLS), stereolithography (SLA), digital light processing (DLP), direct metal laser sintering (DMLS), laser net shape manufacturing (LNSM), electron beam sintering, or other known additive processes. An additive process fabricates components using three-dimensional information of the component, for example, a three-dimensional computer model of the component. The three-dimensional information is converted into a plurality of slices, each slice defining a cross section of the component for a predetermined height of the slice. The component is then “built-up” slice by slice, or layer by layer, until finished.

Accordingly, at step 810, three-dimensional information of unitary user interface panel 124 is determined. As an example, a model or prototype of unitary user interface panel 124 may be scanned to determine the three-dimensional information of the panel. As another example, a model of unitary user interface panel 124 may be constructed using a suitable CAD program to determine the three-dimensional information of the panel. At step 820, the three-dimensional information is converted into a plurality of slices that each defines a cross-sectional layer of unitary user interface panel 124. For example, the three-dimensional information from step 810 may be divided into equal sections or segments, e.g., along a central axis of the panel or any other suitable axis. Thus, the three-dimensional information from step 810 may be discretized at step 820, e.g., to provide planar cross-sectional layers of unitary user interface panel 124.

After step 820, unitary user interface panel 124 is fabricated using an additive process, or more specifically, each layer is successively formed at step 830, e.g., by fusing or polymerizing a suitable material using laser energy or heat. The layers may have any suitable size. For example, each layer may have a size between about five ten-thousandths of an inch and about one thousandths of an inch. Unitary user interface panel 124 may be fabricated using any suitable additive manufacturing machine. For example, any suitable laser sintering machine, inkjet printer, or laserjet printer may be used at step 830.

Unitary user interface panel 124, formed using method 700, method 800, or another appropriate method, has integral traces 132 and allows control components 130 to be mounted directly to panel 124. As such, unitary panel 124 may permit more complex, different, or more effective user interface designs. For example, the curvature of unitary user interface panel 124 is limited by the process used to form the user interface panel 124 rather than the geometry required to mate a flat PCB to a curved panel, which expands the opportunities to form curved user interface panels. Further, without features for mounting control components 130 directly to panel 124, additional components or considerations may be required to effectively and reliably facilitate interaction between the control components and a user of the appliance. For example, in known user interface designs, light emitting control components such as light 130d may be mounted far from a surface of the user interface panel that permits light to pass through; as such, additional components, such as light pipes or guides, may be required to effectively channel light from the light component 130d to the user. However, by mounting light control component 130d directly to user interface panel 124, may eliminate the use of additional components or other design considerations to effectively channel light to the user. As another example, in known user interface designs, micro-switches 130a often are mounted far from the user interface panel having input selectors 126 with which the user interacts. As such, additional components or design considerations may be required to transfer user interaction with input selectors 126 to micro-switch 130a; the additional components or considerations may decrease the reliability of communication between input selector(s) 126 and switch 130a and can affect the “feel” of the component to the user. By mounting switch or micro-switch control component 130a directly to user interface panel 124, user interaction with input selectors 126 may be more reliably transferred to switch 130a with a more consistent feel to the user. Unitary user interface panel 124 may have other advantages and benefits as well.

This written description uses examples to disclose the invention, including the best mode, and also to enable any person skilled in the art to practice the invention, including making and using any devices or systems and performing any incorporated methods. The patentable scope of the invention is defined by the claims and may include other examples that occur to those skilled in the art. Such other examples are intended to be within the scope of the claims if they include structural elements that do not differ from the literal language of the claims or if they include equivalent structural elements with insubstantial differences from the literal language of the claims.

What is claimed is:

1. A user interface for an appliance, the user interface comprising:
a user interface panel; and
a control component attached to the user interface panel,
wherein the user interface panel includes a plurality of traces for providing an electrical connection for the control component, and
wherein the plurality of traces are integrally formed with the user interface panel such that the plurality of traces and the user interface panel are a single, unitary component.

2. The user interface of claim 1, wherein the control component is a surface mount component.

3. The user interface of claim 2, wherein the user interface panel defines two adjacent apertures, wherein a trace of the plurality of traces extends through each aperture, and wherein the surface mount component is mounted to the user interface panel in electrical connection with the trace extending through the two apertures.

4. The user interface of claim 1, wherein the control component is a through hole component.

5. The user interface of claim 4, wherein the user interface panel defines at least two through holes extending through a trace of the plurality of traces, wherein the through hole component comprises at least two legs, and wherein the through hole component is mounted to the user interface panel such that the at least two legs extend through the at least two through holes such that the through hole component is in electrical connection with the trace.

6. The user interface of claim 1, wherein the plurality of traces comprises a capacitive touch sensing matrix of traces.

7. The user interface of claim 1, wherein the plurality of traces is integrally formed with the user interface panel using a laser direct structuring process.

8. The user interface of claim 1, further comprising a plurality of control components, and wherein the plurality of traces electrically connects the control components with at least one connector providing power to the control components.

9. A user interface for an appliance, the user interface comprising:
a user interface panel; and
a control component attached to the user interface panel,
wherein the user interface panel includes a plurality of traces for providing an electrical connection for the control component,
wherein the plurality of traces are integrally formed with the user interface panel such that the plurality of traces and the user interface panel are a single, unitary component, and
wherein the unitary user interface panel is curved.

10. The appliance of claim 9, wherein the unitary user interface panel is curved along a first direction.

11. The appliance of claim 9, wherein the unitary user interface panel is curved along a first direction and a second direction.

12. The appliance of claim 9, wherein the plurality of traces is integrally formed with the user interface panel using a laser direct structuring process.

13. The appliance of claim 9, wherein the control component is a surface mount component.

14. The appliance of claim 9, wherein the control component is a through hole component.

15. A method for forming a unitary user interface of an appliance, the method comprising:
establishing courses of a plurality of traces of the unitary user interface;
converting the courses into control data for use in a laser direct structuring process; and
integrally forming the plurality of traces with a user interface panel using the laser direct structuring process, the integral user interface panel and traces forming a unitary user interface panel.

16. The method of claim 15, wherein integrally forming the plurality of traces with the user interface panel comprises using an injection molding process to form the user interface panel.

17. The method of claim 15, further comprising attaching a control component to the unitary user interface panel.

18. The method of claim 17, wherein the control component is attached to the unitary user interface panel by surface mounting the control component to the user interface panel.

19. The method of claim 17, further comprising forming two through holes in the unitary user interface, the through holes extending through a trace of the plurality of traces.

20. The method of claim 19, wherein the control component comprises two legs, and wherein the control component is attached to the unitary user interface panel by positioning one leg of the control component in each of the two through holes.
